(19) United States
(12) Patent Application Publication
(10) Pub. No.: US 2004/0048473 A1
(43) Pub. Date: Mar. 11, 2004

(54) Method for producing an integrated circuit, at least partially transforming an oxide layer into a conductive layer

(76) Inventors: Wolfram Karcher, Langebruck (DE); Dieter Zeiler, Ottendorf-Okrilla (DE); Matthias Lehr, Dresden (DE)

Correspondence Address: FISH & RICHARDSON PC, 225 FRANKLIN ST, BOSTON, MA, 02110, US

(21) Appl. No.: 10/415,416

(22) PCT Filed: Sep. 25, 2001
(86) PCT No.: PCT/EP01/11076

(30) Foreign Application Priority Data
Nov. 6, 2000 (DE) 100 54 936.5

(51) Int. Cl. H01L 21/302; H01L 21/461

(52) U.S. Cl. 438/689

(57) ABSTRACT

A method for fabricating an integrated circuit includes providing an intermediate layer on first and second metallization regions on a substrate. The intermediate layer above the first metallization region is then etched away, thereby allowing an oxide film to form above the first metallization region. Chemical vapor deposition is then performed using a gas having constituents that include the metal used for the metallization regions and a halogen. This partially converts the oxide layer into a conductive compound in electrical communication with the first metallization region.

The present invention relates to a method for fabricating an integrated circuit with partial conversion of an oxide layer into a conductive layer.

JP 2000-124175 A discloses a method for fabricating an integrated circuit, an insulating layer being applied to a first metalization plane, contact holes being formed in said layer. On the resulting structure, a metal layer for the contacts is applied and is subsequently polished back, so that it remains only in the contact holes. Afterward, an oxide layer produced by the polishing is cleaned from the top sides of the contacts by etching.

JP 3-76632 A and JP 2000-91556 A disclose the conversion of tungsten oxide layers and the suppression of their arising.

DE 199 01 210 A1 discloses the etching of a layer made of tungsten oxide by means of a halogen compound in an oxidizing atmosphere.

Although applicable to arbitrary integrated circuits, in principle, the present invention and the problem area on which it is based are explained with regard to integrated circuits using silicon technology.

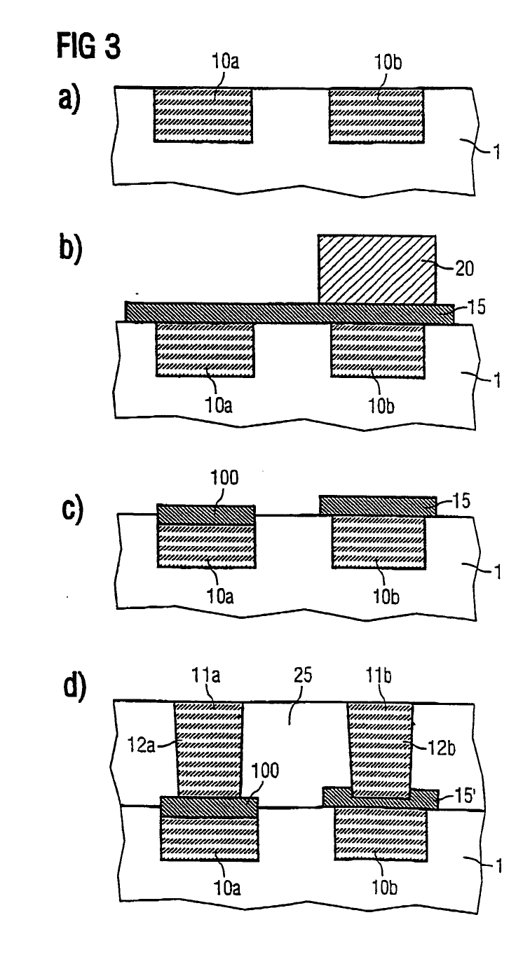

FIGS. 3a-d show diagrammatic illustrations of different process steps of a known method for fabricating an integrated circuit using silicon technology.

In FIG. 3a, reference symbol 1 designates a circuit substrate made of silicon dioxide, into which two metalization regions 10a, 10b made of tungsten are introduced. This introduction of the metalization regions 10a, 10b can be effected for example by a procedure in which, after a trench etching, tungsten is deposited over the whole area of the circuit substrate 1 and is then removed by chemical mechanical polishing in such a way that the separate metalization regions 10a, 10b are produced.

What is intended to be achieved by the method shown is that, in addition to standard tungsten contacts on the first metalization region 10a, a second type of contacts is also created in which an intermediate layer 15 lies on the second metalization region, contact being made with said intermediate layer from above by means of a contact. In the present case, the intermediate layer serves as a fusible link and comprises SiN/WSiₓ. However, it could also be a metallic barrier layer.

As shown in FIG. 3b, in a subsequent process step, the intermediate layer 15 made of SiN/WSiₓ is deposited over the resulting structure, so that it covers the first and second metalization regions 10a, 10b. In a subsequent process step, a photomask 20 is formed in such a way that it covers the intermediate layer 15 above the second metalization region 10b, but leaves free the intermediate layer 15 above the first metalization region 10a.

With reference to FIG. 3b, an etching process and a resist stripping then take place, for example in an NF₃-containing plasma, in order to remove the intermediate layer 15 above the first metalization region 10a. During this etching operation and also during the resist stripping, an oxide film 100 made of WOₓ forms above the tungsten of the first metalization region 10a. It is disadvantageous that the formation of such a WOₓ layer cannot be avoided.

In accordance with FIG. 3d, after the preceding process step, an insulating layer 25, e.g. made of silicon dioxide, is deposited over the whole area of the resulting structure. Afterward, contact holes 12a, 12b are formed above the first and second metalization regions 10a, 10b, respectively, and they are filled with contacts 11a, 11b made of tungsten. This last process of filling with the contacts can be accomplished analogously to the formation of the first and second metalization regions 10a, 10b by tungsten being deposited over the whole area of the structure with the contact holes 12a, 12b and then being partially removed again by means of chemical mechanical polishing.

As can be gathered from FIG. 3d, the oxide film 100 is preserved in the case of the known process, for which reason the contact resistance between the contact 11a and the first metalization region 10a is undesirably increased.

Thus, the general problem area on which the present invention is based is that the surfaces of specific metal layers or tracks can oxidize, e.g. when using tungsten as metal, under the action of specific etching gases at the surface.

By way of example, such WOₓ layers have the disadvantage that they have a significantly higher resistance than pure tungsten, which means that the contact resistance with respect to overlying planes connected thereto by means of a contact is increased. Furthermore, part of the tungsten is consumed when the WOₓ layers are produced, as a result of which the sheet resistance of the tungsten track is increased and the planarity is disrupted.

Therefore, it is an object of the present invention to provide a method for fabricating an integrated circuit, it being possible to counteract a contact impairment and bulk resistance increase through the etching of the intermediate layer or the resist stripping.

According to the invention, this object is achieved by means of the fabrication method specified in claim 1.

The idea on which the present invention is based consists in at least partially converting the oxide film above the first metalization region in such a way that a conductive compound is produced from the first metal by means of the oxide film and forms a connection to the first metalization region at the surface of the resulting structure.

The fabrication method according to the invention has the advantage, inter alia, over the known solution approach that the contact resistance in the case of the contact without an intermediate layer is considerably reduced and the bulk resistance is reduced.

A further advantage is that the process step for converting the oxide film can be carried out in situ directly after the process step for etching the intermediate layer, preferably in the same process reactor.

A further advantage is that the conversion has the effect of at least partially reversing the increase in volume and hence change in topology as a result of the formation of the oxide film.

Advantageous developments and improvements of the fabrication method specified in claim 1 are found in the subclaims.

In accordance with one preferred development, the intermediate layer is patterned in such a way that it forms a connection to the second metalization region at the surface of the resulting structure.

In accordance with a further preferred development, the first metal is tungsten, the gas comprising WF₆.

In accordance with a further preferred development, an insulation layer is deposited over the resulting structure and a first contact for making contact with the first metalization region and a second contact for making contact with the intermediate layer above the second metalization region are provided in said insulation layer.

In accordance with a further preferred development, the material of the intermediate layer is SiN/WSiₓ. The intermediate layer is thus formed as a fusible link.

An exemplary embodiment of the invention is illustrated in the drawings and explained in more detail in the description below.

In the figures:

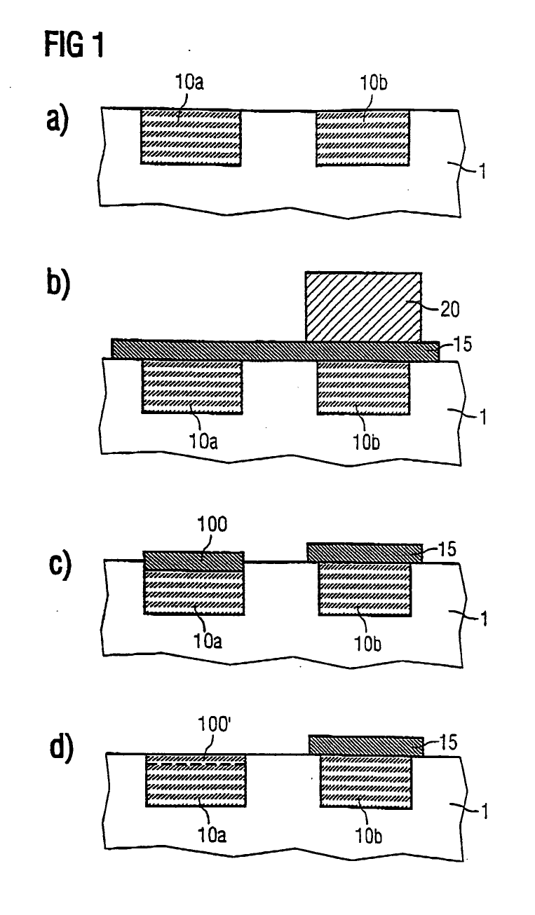

FIGS. 1a-e show diagrammatic illustrations of different process steps of a method for fabricating an integrated circuit using silicon technology as an embodiment of the present invention;

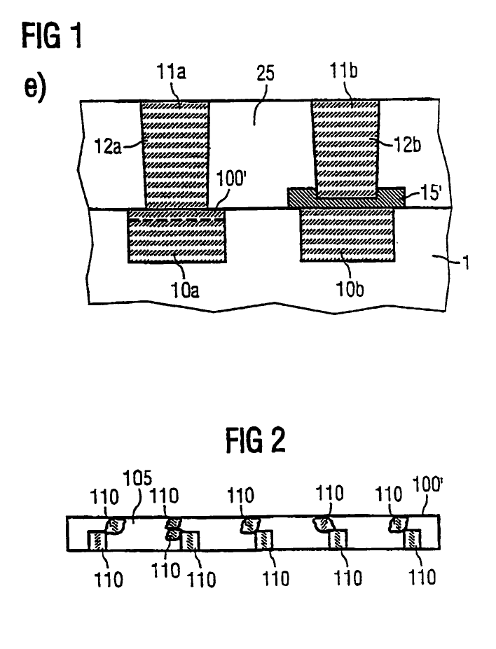

FIG. 2 shows an enlarged diagrammatic illustration of the region 100′ in FIG. 1e; and

FIGS. 3a-d show diagrammatic illustrations of different process steps of a known method for fabricating an integrated circuit using silicon technology.

In the figures, identical reference symbols designate identical or functionally identical component parts.

FIGS. 1a-e show diagrammatic illustrations of different process steps of a method for fabricating an integrated circuit using silicon technology as an embodiment of the present invention, and FIG. 2 shows an enlarged diagrammatic illustration of the region 100′ in FIG. 1e.

The process steps illustrated in FIGS. 1a to 1c correspond to the process steps in accordance with FIGS. 3a to 3c already described in the introduction. A repeated description is therefore dispensed with.

The crux of the embodiment described lies in the process step which is illustrated in connection with FIG. 1d. In this process step, the oxide film 100 made of WOₓ is at least partially converted by means of a CVD process using the gas WF₆ and optionally Ar at a temperature of 400 to 500° C. In this connection, at least partially converted means that the oxide film 100 is converted into a film 100′ having insulating small tungsten oxide islands 105 and conductive small tungsten islands 110, connected small tungsten islands forming shunts which constitute a connection from the first metalization region 10a to the surface of the film 100′.

This is clearly discernible in FIG. 2, which illustrates an enlarged diagrammatic illustration of the region 100′.

The following reactions are used to elucidate this conversion phenomenon:

3WO_{3+/-x}+H₂O+WF₆=4WO₃+6HF; 2HF+WO₃=WO₂F₂+H₂O

In the subsequent process step illustrated in conjunction with FIG. 1e, analogously to FIG. 3d, an insulation film 25 is formed on the surface of the resulting structure, after which contact holes 12a, 12b are etched. Said contact holes 12a, 12b are subsequently filled with tungsten contacts 11a, 11b in order to make contact with the first metalization region directly by means of the contact 11a and to make contact with the second metalization region 10b by means of the contact 11b with the interposition of the (slightly incipiently etched) intermediate layer 15′.

What is achieved, then, with this process step according to the invention is that the WOₓ is at least partially converted back to W and, as a result, contact is made with the first metalization region 10a with a reduced contact resistance and bulk resistance in comparison with the prior art.

Although the present invention has been described above using a preferred exemplary embodiment, it is not restricted thereto, but rather can be modified in diverse ways.

In particular, the selection of the layer materials and etchants is only by way of example and can be varied in many different ways.

List of Reference Symbols

| 10a | First metalization region |
|---|---|
| 10b | Second metalization region |
| 1 | Circuit substrate |
| 15, 15′ | Intermediate layer |
| 20 | Photomask |
| 100 | Oxide film |
| 100′ | Oxide film with shunts made of metal |
| 25 | Insulation layer |
| 12a, 12b | Contact holes |
| 11a, 11b | Contacts |
| 105 | Oxide region |
| 110 | Metallic shunt |

1. A method for fabricating an integrated circuit having the following steps:
provision of a circuit substrate (1);
provision of a first metalization region (10a) and a second metalization region (10b) made of a first metal in the circuit substrate (1);
provision of an intermediate layer (15) above the first metalization region (10a) and the second metalization region (10b);
removal of the intermediate layer (15) above the first metalization region (10a) by means of an etching process with simultaneous formation of an oxide film (100) above the first metalization region (10a); and
at least partial conversion of the oxide film (100) above the first metalization region (10a), so that a conductive compound is produced from the first metal by means of the oxide film (100) and forms a connection to the first metalization region (10a) at the surface of the resulting structure;
the conversion being carried out by means of a CVD process using a gas whose constituents comprise at least the first metal and a halogen.

2. The method as claimed in claim 1,
characterized
in that the intermediate layer (15) is patterned in such a way that it forms a connection to the second metalization region (10b) at the surface of the resulting structure.

3. The method as claimed in claim 1 or 2,
characterized
in that the first metal is tungsten and the gas comprises WF₆.

4. The method as claimed in one of the preceding claims,
characterized
in that an insulation layer (25) is deposited over the resulting structure and a first contact (11a) for making contact with the first metalization region (10a) and a second contact (11b) for making contact with the intermediate layer (15′) above the second metalization region (10b) are provided in said insulation layer.

5. The method as claimed in one of the preceding claims,
characterized
in that the material of the intermediate layer (15) is SiN/WSiₓ.
